(19) United States
(12) Patent Application Publication
(10) Pub. No.: US 2006/0273467 A1
(43) Pub. Date: Dec. 7, 2006

(54) FLIP CHIP PACKAGE AND METHOD OF CONDUCTING HEAT THEREFROM

(75) Inventors: Scott D. Brandenburg, Kokomo, IN (US); Michael J. Varnau, Russiaville, IN (US); Matthew R. Walsh, Sharpsville, IN (US)

Correspondence Address: DELPHI TECHNOLOGIES, INC., M/C 480-410-202, PO BOX 5052, TROY, MI, 48007, US

(73) Assignee: DELPHI TECHNOLOGIES, INC., Kokomo, IN (US)

(21) Appl. No.: 11/160,013

(22) Filed: Jun. 6, 2005

(51) Int. Cl. H01L 21/50; H01L 23/52

(52) U.S. Cl. 257/778; 438/108; 257/788; 438/124

(57) ABSTRACT

A flip chip package and method for conducting heat from one or more flip chips within the package. The package includes a substrate having a first surface to which the flip chips are attached with solder connections, a second surface with solder balls electrically connected to the solder connections on the first surface, and a heat-spreading member bonded to the flip chips and to the first surface of the substrate with bond materials. The method includes reflow soldering the flip chips to the first surface of the substrate, attaching the solder balls to the second surface of the substrate, applying a bond material to the flip chips and a second bond material to the substrate, placing the heat-spreading member on the bond materials, and then applying heat to bond the heat-spreading member to the flip chips and substrate with the bond materials.

### BACKGROUND OF THE INVENTION

The present invention generally relates to flip chip semiconductor devices. More particularly, this invention relates to a method and assembly for thermal management of flip chip packages, and particularly multichip and single chip modules (MCM and SCM).

Integrated circuit (IC) devices generate heat during their operation, resulting in increased junction temperatures for the devices. Because IC reliability and function are adversely affected by high junction temperatures, various techniques for removing heat from IC devices have been proposed. One approach entails the use of a thermally-conductive substrate or a substrate structurally modified to promote its heat conduction capability. Thermal management with such substrates is usually achieved by dissipating heat primarily in the vertical, or “z” direction, beneath the semiconductor device. For example, heat-generating semiconductor chips, such as power flip chips, are often mounted to alumina substrates that conduct and dissipate heat in the vertical direction beneath the chip.

Another approach used with IC packages involves placing an IC device in contact with a metal slug or an internal frame, which conducts thermal energy from the IC device to a surface of the package. Heat is then removed from the package surface by conduction into a separate heat sink or into the circuit board on which the package is mounted. In the case of a surface mount (SM) IC device requiring wire bonding to a printed circuit board (PCB), the heat sink (such as a copper slug) is soldered to the opposite side of the device as the device input/output (I/O) pads, and heat is conducted through the heat sink and into the PCB. Because the primary heat sink path is through the PCB, heat removal from the IC device is limited.

More recently, commonly-assigned U.S. Pat. Nos. 6,180,436, 6,262,489, and 6,873,043 and U.S. Patent Application Publication Nos. 2005/0040518 and 2005/0078456 teach thermal management techniques compatible with flip chips on PCB's by making use of heat sinks with pedestals that contact the back side of the chip, i.e., the surface of the chip opposite the surface on which its microcircuitry is formed. While successful when individually addressing power flip chips mounted directly to a PCB, utilizing this thermal management approach with SCM's and MCM's, such as ball grid array (BGA) packages, is complicated by the tolerance stack up due to differences in solder bump collapse heights and the chip-to-chip thickness variations that exist between the multiple flip chips of an MCM.

### BRIEF SUMMARY OF THE INVENTION

The present invention provides a flip chip package and method for conducting heat from the package. The invention is particularly adapted for SCM's and MCM's, including BGA packages, containing power flip chips.

The package comprises a substrate having oppositely-disposed first and second surfaces and conductors on the first surface, solder balls on the second surface of the substrate and electrically connected to the conductors on the first surface, at least one flip chip having a first surface facing away from the substrate and an oppositely-disposed second surface with solder connections registered with the conductors on the substrate, and a heat-spreading member bonded to the first surface of the flip chip and bonded to the first surface of the substrate.

The method of the invention includes reflow soldering at least one flip chip to conductors on a first surface of a substrate so that a first surface of the flip chip faces away from the substrate and an oppositely-disposed second surface faces the substrate, attaching solder balls to a second surface of the substrate opposite the first surface thereof and electrically connected to the conductors on the first surface, applying a first bond material to the first surface of the flip chip and a second bond material on the substrate, placing a heat-spreading member so as to contact the first and second bond materials, and then applying heat to simultaneously bond the heat-spreading member to the flip chip and the substrate with the first and second bond materials.

The method of this invention and the resulting flip chip package are able to provide a high performance thermal path from a heat-generating flip chip to a heat sink, in the form of a heat spreader capable of absorbing heat and conducting heat to, for example, the substrate or an external heat sink. The method and package also enable the use of flip chip devices in applications where manufacturing and processing limitations discourage or prevent the use of flip chip processing and assembly by providing prepackaged flip chips in a rugged module (such as a BGA module) within which the chips are encased and protected.

Other objects and advantages of this invention will be better appreciated from the following detailed description.

### BRIEF DESCRIPTION OF THE DRAWINGS

FIGS. 1 and 2 are plan and cross-sectional views, respectively, depicting a multichip BGA module in accordance with a first embodiment of the present invention.

FIG. 3 is a cross-sectional views depicting an overmolded multichip BGA module in accordance with a second embodiment of the present invention.

FIG. 4 represents molding equipment suitable for producing the module of FIG. 3.

### DETAILED DESCRIPTION OF THE INVENTION

FIGS. 1 through 3 represent multichip BGA packages 10 and 110 in accordance with two embodiments of this invention. Each package 10 and 110 is shown as a multichip module (MCM), though single chip modules (SCM) are also within the scope of the invention.

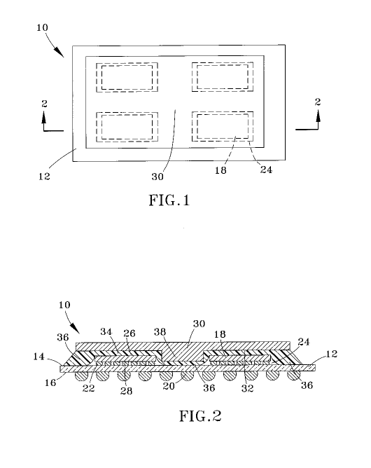

Referring to FIGS. 1 and 2, the BGA package 10 is represented as including a substrate 12 on whose upper surface 14 are attached flip chips 18, such as power flip chips used in powertrain control module (PCM) for automotive applications. The substrate 12 is preferably a thin laminate PCB, though other constructions could be used. The lower surface 16 of the substrate 12 is equipped with solder balls 20 that permit reflow soldering of the BGA package 10 to, for example, a motherboard (not shown). The flip chips 18 are electrically connected to conductors (not shown) on the upper surface 14 of the package 10 with solder connections 22 located on the lower surfaces (front side) 28 of the chips 18 (the surfaces of the chips 18 on which their flip chip microcircuitries are formed). The solder connections 22 are electrically interconnected with the solder balls 20 by plated through-holes (not shown) or other suitable structures within the substrate 12 to provide electrical communication between the chips 18 and the motherboard to which the package 10 will be attached. The motherboard may be populated with other circuit devices as necessary for the intended application, for example, a PCM.

The solder balls 20 are preferably formed of a solder material with a lower reflow temperature than that of the solder connections 22 to permit reflow soldering of the package 10 after reflow soldering of the chips 18 to the substrate 12. The chips 18 are shown as being underfilled with a suitable polymeric underfill material 24, as is conventionally done in the art to promote the thermal cycle life of flip chip solder connections. As shown, the underfill material 24 is preferably limited to encapsulating the solder connections 22 of the chips 18, and is therefore localized around each chip 18 as evident from FIG. 1. Suitable reflow and underfill techniques, solders, and underfill materials are well known in the art and therefore will not be discussed in any detail here.

FIGS. 1 and 2 show the package 10 as further including a heat spreader 30 in thermal contact with an upper surface (backside) 26 of each flip chip 18. The heat spreader 30 is preferably a metal plate, such as aluminum or copper, to promote the thermal properties of the spreader 30, though the use of other materials are foreseeable. As depicted in FIGS. 1 and 2, the lower surface of heat spreader 30 has coplanar surface regions 32 aligned with and bonded to the upper surfaces 26 of the chips 18 with a bond material 34 that contacts the chip surfaces 26 and the surface regions 32 of the heat spreader 30. The bond material 34 is preferably a solder or an thermal adhesive, since heat dissipated by the chips 18 is primarily conducted to the heat spreader 30 through the bond material 34. Similar to the solder balls 20 of the substrate 12, the bond material 34 is capable of being reflowed or cured (as the case may be) at a temperature lower than the reflow temperature of the solder connections 22 to permit bonding of the heat spreader 30 to the chips 18 after the chips 18 have been reflow soldered to the substrate 12. For this reason, a suitable solder for the bond material 34 is indium (melting point of about 157° C.), an indium-based solder composition, or another low-melting solder. To permit the use of solder as the bonding material 34, the upper surfaces 26 of the chips 18 are preferably provided with a thin layer of gold or other sufficiently solderable material, while the lower surface of the heat spreader 30 may be covered with a tin plating to promote solderability.

If the bond material 34 is formed of an adhesive, heat transfer can be promoted by forming the material 34 to contain an adhesive matrix material (e.g., an epoxy) that contains a dispersion of metal and/or ceramic particles. While heat transfer through the bond material 34 can be promoted by minimizing the thickness of the bond material 34, a thicker bond joint is desirable for this invention because, while the upper surfaces 26 of the flip chips 18 may be nearly coplanar, there is inevitably variation from chip to chip because of differences in collapse heights of the solder connections 22 and variations in the thicknesses of the chips 18. A thick bond joint formed by a thermally-conductive bond material 34 is able to accommodate the resulting tolerance stack up (e.g., up to about 50 micrometers) without incurring unacceptably high thermal resistance. For this reason, the bond joint formed by the bond material 34 is at least 50 micrometers thick, and more preferably at least 100 micrometers thick.

The heat spreader 30 is also shown in FIG. 2 as being directly bonded to the upper surface 14 of the substrate 12 with a second bond material 36, preferably a polymeric structural adhesive 36 that contacts the upper surface 14 of the substrate 12 and those portions of the lower surface of the heat spreader 30 that are not contacted by the flip chips 18. Suitable structural adhesives 36 include epoxies and filled epoxies well known in the art. The heat spreader 30 is shown as having a pedestal 38 defined on its lower surface that projects between the chips 18. The pedestal 38 helps to establish the widths of the gaps between the upper surfaces 26 of the chips 18 and the lower surface 32 of the heat spreader 30, as well as promote the stability of the heat spreader 30 during the assembly process.

The package 10 can be produced by a process that includes mounting the flip chips 18 to the BGA substrate 12 using a conventional flip-chip technique, in which preformed solder bumps on the front sides (lower surfaces 28 as viewed in FIG. 2) of the chips 18 are registered with and reflow soldered to the conductors on the upper surface 14 of the substrate 16 to yield the solder connections 22. While a variety of solders could be used, a suitable solder for the connections 22 is 70Pb-30Sn, with a peak reflow temperature of about 260° C. to about 280° C. The chips 18 are then underfilled, such as with a known capillary or no-flow underfill material. Curing of the underfill material 24 can be performed at temperatures (e.g., up to about 165° C.) well below the reflow temperature of the solder connections 22. The solder balls 20 are then placed on the lower surface 16 of the BGA substrate 12, and then reflowed at a temperature (e.g., up to about 230° C.) below the reflow temperature of the solder connections 22. The solderable back sides (upper surfaces 26 as viewed in FIG. 2) of the chips 18 are then fluxed (if necessary), bond material 34 is deposited on the chips 18, and the structural adhesive 36 is dispensed on the surface regions of the substrate 12 left exposed by the chips 18. Thereafter, the heat spreader 30 is placed on the bond material 34 and structural adhesive 36, after which the resulting assembly undergoes a heating step in which the bond material 34 is reflowed or cured (depending on the composition of the bond material 34) and the structural adhesive 36 is cured. Use of an indium solder for the bond material 34 permits a combined reflow-cure process at a temperature (e.g., up to about 170° C.) well below the reflow temperatures of the solder connections 22 and solder balls 20.

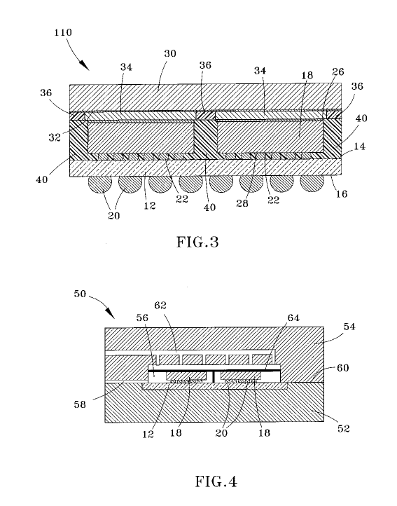

The second embodiment of the invention depicted in FIG. 3 is similar to that of FIGS. 1 and 2 (the same reference numbers identifying like components), with the exception that the flip chips 18 are encased within an overmold compound 40, yielding a relatively small but rugged package 110. With the embodiment of FIG. 3, the heat spreader 30 is bonded to the substrate 12 with the structural adhesive 36, which contacts the heat spreader 30 and the overmold compound 40 molded onto the substrate 12.

The process of producing the package 110 can differ from that of the package 10 solely by substituting an overmolding operation for the underfilling operation. As evident from FIG. 3, the overmold compound 40 also preferably underfills the chips 18. Such a process can be carried out with the molding apparatus 50 depicted in FIG. 4, which is representative of soft clamp molding technology available from various suppliers of IC molding equipment. The apparatus 50 includes lower and upper mold halves 52 and 54 that together define a mold cavity 56 in which the subassembly formed by substrate 12 and chips 18 (without solder balls 20) is placed. The uncured overmold compound is injected into the cavity 56 through a gate 58, and a vent 60 is provided to allow air to escape the cavity 56 during the injection process. The apparatus 50 is advantageous for overmolding the subassembly because of its ability to apply a controlled load on the subassembly without damaging the subassembly, particularly the relatively fragile solder connections 22 that remain unprotected at this assembly level. As indicated in FIG. 4, a controlled load is applied with compressed air routed into the upper mold half 54 through a duct 62. The compressed air preferably generates a force that is applied through a protective film release 64 that prevents the overmold compound from being deposited onto the upper surfaces 26 of the chips 18 and, on curing of the overmold compound 40, defines a relatively flat upper surface on the overmold compound 40. As with the underfill material 24 of the first embodiment, injection and curing of the overmold compound 40 is performed at temperatures (e.g., up to about 165° C.) well below the reflow temperature of the solder connections 22.

While our invention has been described in terms of a preferred embodiment, it is apparent that other forms could be adopted by one skilled in the art. Accordingly, the scope of our invention is to be limited only by the following claims.

1. A flip chip package comprising:
a substrate having oppositely-disposed first and second surfaces and conductors on the first surface;
solder balls on the second surface of the substrate and electrically connected to the conductors on the first surface;
at least one flip chip mounted to the first surface of the substrate, the flip chip having oppositely-disposed first and second surfaces and solder connections on the second surface thereof registered with the conductors on the substrate; and
a heat-spreading member having a surface facing the flip chip and substrate bonded to the first surface of the flip chip with an indium solder material and bonded to the first surface of the substrate by a polymeric structural adhesive material.

2. The flip chip package according to claim 1, wherein the flip chip package further comprises at least a second flip chip mounted to the first surface of the substrate, the second flip chip having oppositely-disposed first and second surfaces and solder connections on the second surface thereof registered with the conductors on the substrate.

3. The flip chip package according to claim 2, wherein the first surfaces the flip chip and the second flip chip are not coplanar.

4. The flip chip package according to claim 3, wherein the heat-spreading member has coplanar surface regions and the heat-spreading member is bonded to the first surfaces of the flip chip and the second flip chip with a bond material that contacts the coplanar surface regions.

5.-9. (canceled)

10. The flip chip package according to claim 1, further comprising an overmold compound on the first surface of the substrate and in which the flip chip is encased.

11. The flip chip package according to claim 10, wherein the heat-spreading member is bonded to the first surface of the substrate through a polymeric structural adhesive material contacting the heat-spreading member and the overmold compound on the first surface of the substrate.

12.-20. (canceled)

21. The flip chip package according to claim 1, wherein the majority of the surface of the heat-spreading member facing the flip chip and substrate and not bonded to the first surface of any of the at least one flip chip by the indium solder is bonded to the first surface of the substrate by the polymeric structural adhesive material.

22. The flip chip package according to claim 1, wherein all of the surface of the heat-spreading member facing the flip chip and substrate and not bonded to the first surface of any of the at least one flip chip by the indium solder is bonded to the first surface of the substrate by the polymeric structural adhesive material.

23. The flip chip package according to claim 10, wherein the majority of the surface of the heat-spreading member facing the flip chip and substrate and not bonded to the first surface of any of the at least one flip chip by the indium solder is bonded to the first surface of the substrate by the polymeric structural adhesive material.

24. The flip chip package according to claim 10, wherein all of the surface of the heat-spreading member facing the flip chip and substrate and not bonded to the first surface of any of the at least one flip chip by the indium solder is bonded to the first surface of the substrate by the polymeric structural adhesive material.
